(19) United States
(12) Patent Application Publication
(10) Pub. No.: US 2008/0204080 A1
(43) Pub. Date: Aug. 28, 2008

(54) Mobile circuit robust against input voltage change

(75) Inventors: Myoung-hoon Yoon, Incheon (KR); Sang-hoon Lee, Gyeonggi-do (KR)

Correspondence Address: MILLS & ONELLO LLP, ELEVEN BEACON STREET, SUITE 605, BOSTON, MA, 02108, US

(73) Assignee: Samsung Electronics Co., Ltd., Suwon-si (KR)

(21) Appl. No.: 12/004,739

(22) Filed: Dec. 21, 2007

(30) Foreign Application Priority Data
Feb. 22, 2007 (KR) 10-2007-0018098

(51) Int. Cl. H03K 19/10; H03K 19/0175

(52) U.S. Cl. 326/93; 326/134

(57) ABSTRACT

An inverting flip-flop (F/F) circuit type monostable-bistable transition logic element (MOBILE) circuit that uses resonant tunneling diodes (RTDs) and can prevent a malfunction caused by low peak-to-valley current ratio (PVCR) characteristics of the RTD includes an input data conversion circuit and an inverting F/F circuit. The input data conversion circuit receives input data and converts a logic level of the input data according to a logic level of output data of the MOBILE circuit. The inverting F/F circuit inverts a logic level of data output from the input data conversion circuit and outputs the output data. Accordingly, even when a logic level of input data changes from LOW to HIGH, the logic level of output data can be maintained HIGH in the inverting F/F type MOBILE circuit constructed using silicon semiconductor based RTDs with a small PVCR. Therefore, it is possible to enhance the performance of the inverting F/F circuit type MOBILE circuit.

### CROSS-REFERENCE TO RELATED PATENT APPLICATION

This application claims the benefit of Korean Patent Application No. 10-2007-0018098, filed on Feb. 22, 2007, in the Korean Intellectual Property Office, the contents of which are incorporated herein in their entirety by reference.

### BACKGROUND OF THE INVENTION

1. Field of the Invention

The present invention relates to a monostable-bistable transition logic element (MOBILE) circuit, and more particularly, to an inverting flip-flop (F/F) circuit type MOBILE circuit that uses resonant tunneling diodes (RTDs) and can prevent a malfunction caused by small peak-to-valley current ratio (PVCR) characteristics of the RTD.

2. Description of the Related Art

The semiconductor industry has steadily grown from the late 20th century. The core technology of the semiconductor industry can be broadly classified into the miniaturization and the integration of semiconductor devices. Thanks to the miniaturization of semiconductor devices, more devices can be integrated into a unit chip (high degree of integration), the speed of electrons can be increased so as to increase the device operation speed (high operation speed), and the amount of electrons moving can be reduced so as to reduce the device power consumption (low power consumption).

During the past three decades, semiconductor devices have decreased in size to 1/50 of their original size, have increased the degree of integration by 10,000 times, and have increased in operation speed by 1,000 times. Such a trend is expected to continue, and the U.S. semiconductor industry anticipates that the minimum linewidth of metal interconnection will decrease to about 50 nm in 2009.

However, when the minimum linewidth is below 10 nm, electrons are greatly affected by the quantum-mechanical operation and thus the classical principle, which simply treats an electron as an independent electrical particle, cannot be applied as it is now. In order to solve this problem, extensive research is being conducted to develop a quantum device that actively uses a quantum effect.

Examples of a quantum device are a single-electron device, a quantum cellular automaton device, a resonant tunneling diode (RTD) device, and a quantum interference device. Among these devices, the RTD device is best established in conventional technology.

The RTD uses a resonant tunneling effect, which causes an electron with predetermined energy to penetrate a region of a quantum well as if no barrier exists, and has NDR (negative differential resistance) characteristics due to a quantum effect even at room temperature.

The use of the NDR characteristics can reduce the number of devices (components) of a circuit, which has been constructed using only complementary metal oxide semiconductors (CMOSs), thereby achieving low power consumption and a high degree of integration. For example, a CMOS comparator, which has been constructed conventionally using 18 devices, can be constructed using only 6 devices using the NDR characteristics. In addition, the circuit operation speed can be greatly increased using a resonance phenomenon.

The RTD device can be used in a digital circuit such as a flip-flop, a frequency divider, a digital-to-analog converter (DAC), an adder, an analog circuit such as a voltage-controlled oscillator, and a memory device such as a static random access memory (SRAM).

A typical example of a digital circuit using the RTD device is a MOBILE (monostable-bistable transition logic element) circuit. Examples of the MOBILE are disclosed in U.S. Pat. No. 5,313,117, which relates to a semiconductor logic circuit using two N-type negative resistance devices, and IEEE Electron Device Letters, Vol. 16, pp. 70-73, February, 1995, which relates to monolithic integration of FETs and RTDs for MOBILE.

The RTD devices can be classified as silicon semiconductor based RTD devices and compound semiconductor (e.g., GaAs and InP) based RTD devices. The silicon semiconductor based RTD device is low in price and compatible with the conventional CMOS process, but cannot be used in high-frequency circuits. In contrast, the compound semiconductor based RTD device can be used in high-frequency circuits, but is high in price and incompatible with the conventional CMOS process. Accordingly, there is a need for the silicon semiconductor based RTD device to be widely used.

However, the silicon semiconductor based RTD device is small in terms of peak-to-valley current ratio (PVCR) and thus is difficult to use for a wide range of technical fields. In particular, when the MOBILE circuit is constructed using the silicon semiconductor based RTD device and an input voltage margin is small, the number of stable points decreases due to the small-PVCR characteristics of the RTD device, which causes a malfunction in the MOBILE circuit.

### SUMMARY OF THE INVENTION

The present invention provides a monostable-bistable transition logic element (MOBILE) circuit that can provide a stable output independently of an input data change in consideration of peak-to-valley current ratio (PVCR) characteristics of a resonant tunneling diode (RTD).

According to an aspect of the present invention, there is provided a MOBILE (monostable-bistable transition logic element) circuit constructed using RTDs (resonant tunneling diodes). The circuit includes: an input data conversion circuit receiving input data and converting a logic level of input data according to a logic level of output data of the MOBILE circuit; and an inverting F/F (flip-flop) circuit inverting a logic level of data output from the input data conversion circuit and outputting the output data.

In one embodiment the input data conversion circuit operates when the logic level of the output data is HIGH. The input data conversion circuit can operate when the logic level of the input data changes from LOW to HIGH. The input data conversion circuit can convert the logic level of the input data from HIGH to LOW and output the resulting data. The input data conversion circuit can operate when a logic level of a clock signal input into the inverting F/F circuit is HIGH.

In one embodiment, the input data conversion circuit includes: a first transistor receiving output data of the inverting F/F circuit; and a first RTD connected to the first transistor and receiving the input data. The first transistor can have a first terminal connected to an output node of the inverting F/F circuit, a second terminal connected to ground, and a third terminal connected to an output node of the input data conversion circuit. The first RTD can have a first terminal connected to an input node of the input data conversion circuit, and a second terminal connected to the output node of the input data conversion circuit. The inverting F/F circuit can include: a second transistor receiving the data output from the input data conversion circuit as a control signal; a second RTD connected in parallel to the second transistor; and a third RTD connected in series with the second RTD. in one embodiment, the second transistor has a first terminal connected to the output node of the input data conversion circuit, a second terminal connected to the output node of the inverting F/F circuit, and a third terminal connected to ground; the second RTD has a first terminal connected to the output node of the inverting F/F circuit, and a second terminal connected to ground; and the third RTD has a first terminal connected to a clock signal input terminal, and a second terminal connected to the output node of the inverting F/F circuit.

The RTD can be a silicon semiconductor based RTD. The inverting F/F circuit can be an inverted return-to-zero D flip-flop.

According to another aspect of the present invention, there is provided a MOBILE (monostable-bistable transition logic element) circuit constructed using RTDs (resonant tunneling diodes). The circuit includes: an input data conversion circuit receiving input data and outputting data with a logic level LOW independently of a logic level of the input data when a logic level of output data of the MOBILE circuit is HIGH; and an inverting F/F (flip-flop) circuit inverting a logic level of data output from the input data conversion circuit and outputting the output data.

In one embodiment, the input data conversion circuit can operate during a period when a logic level of a clock signal input into the inverting F/F circuit is HIGH.

The input data conversion circuit can include: a first RTD receiving output data of the inverting F/F circuit; a first transistor receiving output data of the first RTD; and a second RTD connected to the first transistor and receiving the input data. The first RTD can have a first terminal connected to an output node of the inverting F/F circuit, and a second terminal connected to a first terminal of the first transistor. The first transistor can have the first terminal connected to the second terminal of the first RTD, a second terminal connected to ground, and a third terminal connected to an output node of the input data conversion circuit. The second RTD can have a first terminal connected to an input node of the input data conversion circuit, and a second terminal connected to the output node of the input data conversion circuit.

The RTD can be a silicon semiconductor based RTD. The inverting F/F circuit can be an inverted return-to-zero D flip-flop.

### BRIEF DESCRIPTION OF THE DRAWINGS

The foregoing and other objects, features and advantages of the invention will be apparent from the more particular description of preferred aspects of the invention, as illustrated in the accompanying drawings in which like reference characters refer to the same parts throughout the different views. The drawings are not necessarily to scale, emphasis instead being placed upon illustrating the principles of the invention.

FIG. 1 illustrates logic devices constructed using resonant tunneling diodes (RTDs).

FIG. 2 is a graph illustrating the I-V characteristics of an RTD.

FIG. 3 is a circuit diagram of a conventional monostable-bistable transition logic element (MOBILE) circuit constructed using RTDs.

FIG. 4 illustrates a first operation of the MOBILE circuit illustrated in FIG. 3.

FIG. 5 illustrates a second operation of the MOBILE circuit illustrated in FIG. 3.

FIG. 6 is a graph illustrating input data margins depending on different peak-to-valley current ratios (PVCRs).

FIG. 7 illustrates a malfunction that occurs when a PVCR is small.

FIG. 8 is a circuit diagram of a MOBILE circuit according to an embodiment of the present invention.

FIG. 9 is a circuit diagram of a MOBILE circuit according to another embodiment of the present invention.

FIG. 10 is a graph illustrating the simulated waveforms of a clock signal, input data, and output data according to an embodiment of the present invention.

### DETAILED DESCRIPTION OF PREFERRED EMBODIMENTS OF THE INVENTION

FIG. 1 illustrates logic devices constructed using resonant tunneling diodes (RTDs).

Referring to FIG. 1, the left diagram in FIG. 1 illustrates an inverter constructed using an RTD, while the right diagram in FIG. 1 illustrates a static random access memory (SRAM) constructed using RTDs.

Unlike a conventional inverter constructed using a P-type metal oxide semiconductor field effect transistor (MOSFET) and an N-type MOSFET, the inverter illustrated in FIG. 1 is constructed using an RTD 110 and an N-type MOSFET 120, which can increase the pull-up speed and reduce the power consumption. In addition, unlike a conventional SRAM that is constructed using four or six transistors, the SRAM illustrated in FIG. 1 is constructed using two RTDs 140 and 150 and two N-type MOSFETs 130 and 160, which can reduce the circuit area and the power consumption.

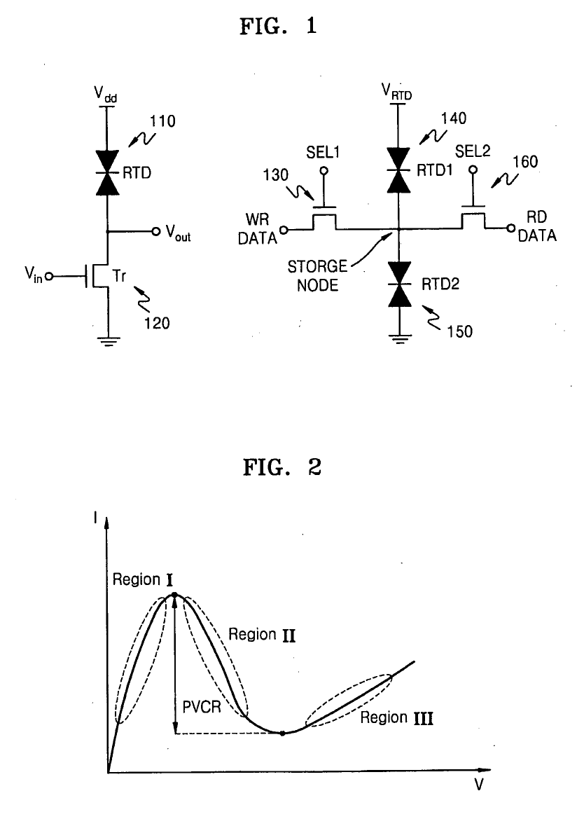

FIG. 2 is a graph illustrating the I-V characteristics of an RTD.

Referring to FIG. 2, an I-V curve of the RTD can be generally divided into three regions. In a first region (Region I), a current increases as a voltage increases. In a second region (Region II), a current decreases as a voltage increases. In a third region (Region III), a current again increases as a voltage increases.

That is, the second region exhibits negative differential resistance (NDR) characteristics. Using the NDR characteristics, the operating speed of the logic device can be increased and the logic device can be constructed using fewer elements than the conventional logic circuit. The ratio of a peak current to a valley current is called a peak-to-valley current ratio (PVCR). The PVCR is used as an important index for determining the characteristics of an RTD.

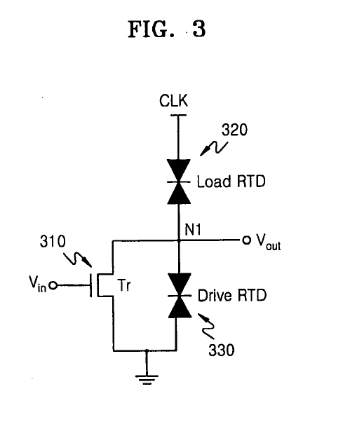

FIG. 3 is a circuit diagram of a conventional monostable-bistable transition logic element (MOBILE) circuit constructed using RTDs.

Referring to FIG. 3, the conventional MOBILE circuit includes a control transistor 310, a load RTD 320, and a drive RTD 330, and performs a function of an inverting flip-flop (F/F) circuit.

The control transistor 310 may be constructed using an N-type MOSFET. The control transistor 310 is connected in parallel to the drive RTD 330. A first terminal of the load RTD 320 is connected to a clock signal input terminal, and a second terminal of the load RTD 320 is connected to a first terminal of the drive RTD 330. The first terminal of the drive RTD 330 is connected to the second terminal of the load RTD 320, and a second terminal of the drive RTD 330 is connected to ground.

Input data Vᵢₙ is applied to a gate of the control transistor 310, and the MOBILE circuit inverts the logic level of the input data Vᵢₙ and outputs the resulting data as output data Vₒᵤₜ. A clock signal CLK is applied to the load RTD 320, and the MOBILE circuit operates by not depending on the logic level of the clock signal CLK. An output node N1 is a common node to which the control transistor 310, the load RTD 320, and the drive RTD 330 are connected.

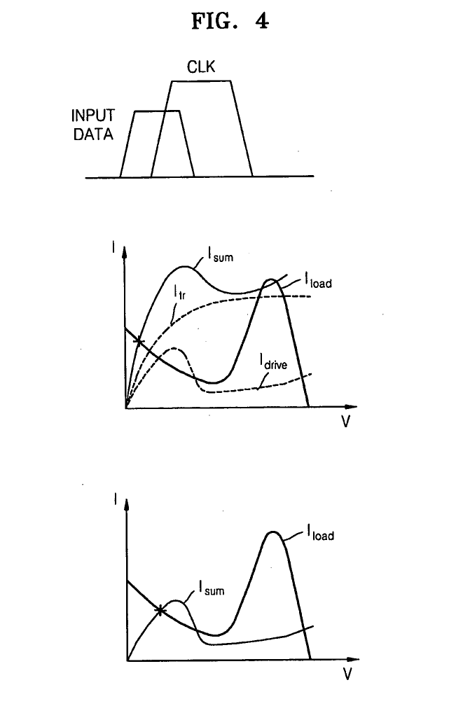

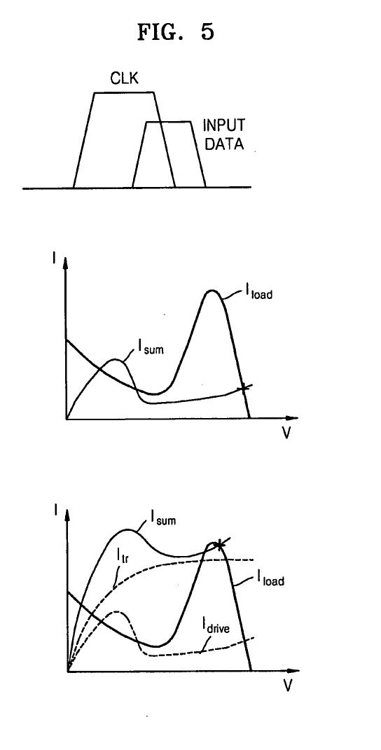

Operation of the MOBILE circuit will now be described in detail with reference to FIGS. 4 and 5.

FIG. 4 illustrates a first operation of the MOBILE circuit illustrated in FIG. 3.

A first diagram in FIG. 4 illustrates the relationship between the input data Vᵢₙ and the clock signal CLK. A second diagram in FIG. 4 is a graph illustrating the state of a load line when the logic level of the input data Vᵢₙ is HIGH. A third diagram in FIG. 4 is a graph illustrating the state of the load line when the logic level of the input data Vᵢₙ is LOW.

Although not illustrated in FIG. 4, when the logic level of the clock signal CLK is LOW, one stable point occurs and the logic level of the output data Vₒᵤₜ is always LOW independently of the logic level of the input data Vᵢₙ.

Referring to the first diagram in FIG. 4, the logic level of the input data Vᵢₙ is HIGH when the logic level of the clock signal CLK transits from LOW to HIGH, and the logic level of the input data Vᵢₙ transits from HIGH to LOW when the logic level of the clock signal CLK is maintained HIGH.

Referring to the second diagram in FIG. 4, two stable points occur when the logic level of the clock signal CLK is HIGH and the logic level of the input data Vᵢₙ is HIGH. Which of the two stable points to select is determined according to the logic level of the input data Vᵢₙ at a time when the logic level of the clock signal CLK transits from LOW to HIGH.

Due to the logic level of the input data Vᵢₙ being HIGH, when the peak value of a sum current Iₛᵤₘ, which is the sum of a current Iₜᵣ flowing through the control transistor 310 and a current I_{drive} flowing through the drive RTD 330, is greater than the peak value of a current I_{load} flowing through the load RTD 320, the first stable point is selected and the logic level of the output data Vₒᵤₜ becomes LOW.

Referring to the third diagram in FIG. 4, two stable points occur when the logic level of the clock signal CLK is HIGH and the logic level of the input data Vᵢₙ is LOW. In this case, the logic level of the output data Vₒᵤₜ is maintained LOW. That is, during the period when the logic level of the clock signal CLK is HIGH, the logic level of the output data Vₒᵤₜ does not change even though the logic level of the input data Vᵢₙ changes.

FIG. 5 illustrates a second operation of the MOBILE circuit illustrated in FIG. 3.

A first diagram in FIG. 5 illustrates the relationship between the input data Vᵢₙ and the clock signal CLK. A second diagram in FIG. 5 is a graph illustrating the state of the load line when the logic level of the input data Vᵢₙ is LOW. A third diagram in FIG. 5 is a graph illustrating the state of the load line when the logic level of the input data Vᵢₙ is HIGH.

Referring to the first diagram in FIG. 5, the logic level of the input data Vᵢₙ is LOW when the logic level of the clock signal CLK transits from LOW to HIGH, and the logic level of the input data Vᵢₙ changes from LOW to HIGH when the logic level of the clock signal CLK is maintained HIGH.

Referring to the second diagram in FIG. 5, two stable points occur when the logic level of the clock signal CLK is HIGH and the logic level of the input data Vᵢₙ is LOW. Which of the two stable points to select is determined according to the logic level of the input data Vᵢₙ at a time when the logic level of the clock signal CLK transits from LOW to HIGH.

Due to the logic level of the input data Vᵢₙ being LOW, when the peak value of a sum current Iₛᵤₘ, which is the sum of a current Iₜᵣ flowing through the control transistor 310 and a current I_{drive} flowing through the drive RTD 330, is smaller than the peak value of a current I_{load} flowing through the load RTD 320, the second stable point is selected and the logic level of the output data Vₒᵤₜ becomes HIGH.

Referring to the third diagram in FIG. 5, two stable points occur when the logic level of the clock signal CLK is HIGH and the logic level of the input data Vᵢₙ is HIGH. In this case, the logic level of the output data Vₒᵤₜ is maintained HIGH. That is, during the period when the logic level of the clock signal CLK is HIGH, the logic level of the output data Vₒᵤₜ does not change even though the logic level of the input data Vᵢₙ changes.

In summary, the logic level of the output data Vₒᵤₜ changes only when the logic level of the clock signal CLK transits from LOW to HIGH or from HIGH to LOW. That is, even though the logic level of the input data Vᵢₙ changes, the logic level of the output data Vₒᵤₜ does not change when the logic level of the clock signal CLK does not change.

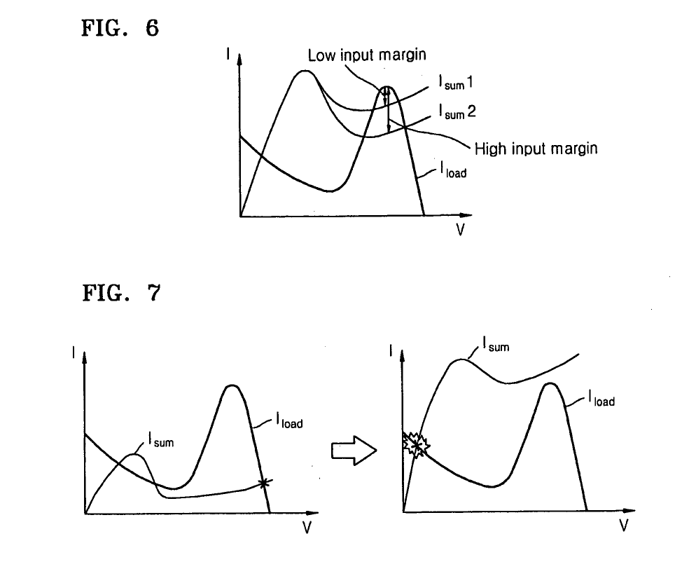

FIG. 6 is a graph illustrating input data margins depending on different PVCRs.

As described above, the PVCR denotes the ratio of a peak current to a valley current. In addition, when the logic level of the input data Vᵢₙ in the MOBILE circuit is HIGH, an input data margin is determined by the difference between the peak value of the current I_{load} and the peak value of the sum voltage Iₛᵤₘ.

Therefore, the input data margin increases/decreases as the PVCR increases/decreases. In particular, a silicon semiconductor based RTD has a smaller PVCR than a compound semiconductor based RTD. Accordingly, there is a high probability that a MOBILE circuit constructed using silicon semiconductor based RTDs may malfunction due to a lack of input data margin.

FIG. 7 illustrates a malfunction that occurs when a PVCR is small.

As described above, under normal conditions, when the logic level of the clock signal CLK is HIGH and the logic level of the input data Vᵢₙ is LOW, the logic level of the output data Vₒᵤₜ is HIGH. In particular, during the period when the logic level of the clock signal CLK is maintained HIGH, the logic level of the output data Vₒᵤₜ is maintained HIGH even when the logic level of the input data Vᵢₙ changes from LOW to HIGH. That is, the selected stable point is not affected by a change in the logic level of the input data Vᵢₙ.

However, if the PVCR is small and the logic level of the input data Vᵢₙ changes from LOW to HIGH, when the peak value of the sum current Iₛᵤₘ (i.e., the sum of the current Iₜᵣ and the current I_{drive}) exceeds the peak value of the current I_{load}, only one stable point occurs and thus the logic level of the output data Vout changes to LOW. That is, the MOBILE circuit malfunctions in such a manner that the logic level of the output data Vₒᵤₜ changes even when the logic level of the clock signal CLK is maintained HIGH.

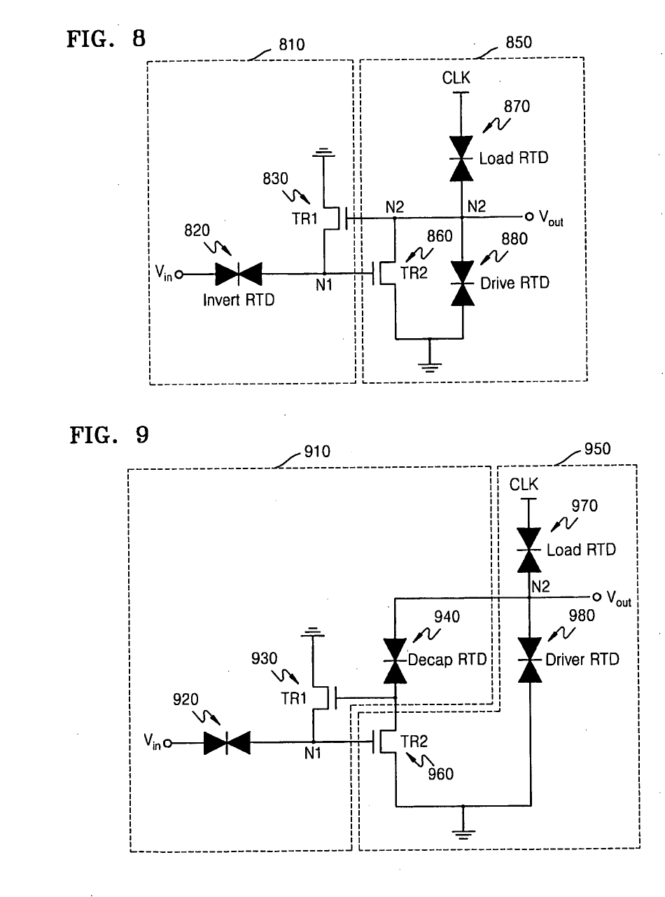

FIG. 8 is a circuit diagram of a MOBILE circuit according to an embodiment of the present invention.

Referring to FIG. 8, a MOBILE circuit according to an embodiment of the present invention includes an input data conversion circuit 810 and an inverting F/F circuit 850.

The input data conversion circuit 810 includes an inverting RTD 820 and a first transistor (TR1) 830.

A first terminal of the inverting RTD 820 is connected to an input node of the input data conversion circuit 810, and a second terminal of the inverting RTD 820 is connected to a first output node N1 of the input data conversion circuit 810. The voltage level of the first output node N1 varies depending on whether the first transistor 830 is turned on or off.

A gate of the first transistor 830 is connected to a second output node N2 of the inverting F/F circuit 850, a drain of the first transistor 830 is connected to ground, and a source of the first transistor 830 is connected to the first output node N1. The first transistor 830 operates according to the voltage of the second output node N2 that is applied to the gate of the first transistor 830. The first transistor 830 may be an N-type MOSFET.

When the voltage level of the second output node N2 of the inverting F/F circuit 850 is HIGH, the first transistor 830 is turned on and thus the voltage of the first output node N1 is pulled down by ground. When the voltage level of the second output node N2 of the inverting F/F circuit 850 is LOW, the first transistor 830 is turned off and thus the voltage of the first output node N1 is not pulled down by ground.

Accordingly, when the voltage level of the second output node N2 is HIGH and the voltage level of the first output node N1 is HIGH, the first transistor 830 inverts the logic level of input data Vᵢₙ. When the voltage level of the first output node N1 or the voltage level of the second output node N2 is LOW, the first transistor 830 inverts the logic level of input data Vᵢₙ.

In summary, the first transistor 830 pulls down the voltage of the first output node N1 when the voltage level of the second output node N2 is HIGH and the voltage level of the first output node N1 changes from LOW to HIGH during the period when the logic level of a clock signal CLK is HIGH. Accordingly, the voltage level of the first output node N1 is constantly maintained LOW during the period when the logic level of the clock signal CLK is HIGH.

The inverting F/F circuit 850 includes a second transistor (TR2) 860, a load RTD 870, and a drive RTD 880. The inverting F/F circuit 850 may be an inverted return-to-zero D flip-flop.

A gate of the second transistor 860 is connected to the first output node N1 of the input data conversion circuit 810, a drain of the second transistor 860 is connected to the second output node N2, and a source of the second transistor 860 is connected to ground. The second transistor 860 operates according to the voltage of the first output node N1 that is applied to the gate of the second transistor 860. The second transistor 860 may be an N-type MOSFET.

A first terminal of the load RTD 870 is connected to a clock signal input terminal, and a second terminal of the load RTD 870 is connected to the second output node N2 of the inverting F/F circuit 850. A first terminal of the drive RTD 880 is connected to the second output node N2 of the inverting F/F circuit 850, and a second terminal of the drive RTD 880 is connected to ground. The drive RTD 880 is connected in parallel to the second transistor 860.

When the voltage level of the first output node N1 of the input data conversion circuit 810 is HIGH, the second transistor 860 is turned on and thus the voltage of the second output node N2 is pulled down by the second transistor 860. When the voltage level of the first output node N1 of the input data conversion circuit 810 is LOW, the second transistor 860 is turned off and thus the voltage of the second output node N2 is not pulled down by the second transistor 860 but instead is pulled up to the voltage level of the clock signal CLK.

FIG. 9 is a circuit diagram of a MOBILE circuit according to another embodiment of the present invention.

Referring to FIG. 9, a MOBILE circuit according to another embodiment of the present invention includes an input data conversion circuit 910 and an inverting F/F circuit 950.

The input data conversion circuit 910 includes an inverting RTD 920, a first transistor (TR1) 930, and a decap (de-capacitance) RTD 940. The inverting RTD 920 has the same structure and function as the inverting RTD 820 in FIG. 8, and thus its description will not be repeated.

A gate of the first transistor 930 is connected to a second terminal of the decap RTD 940, a drain of the first transistor 930 is connected to ground, and a source of the first transistor 930 is connected to a first output node N1 of the input data conversion circuit 910. The first transistor 930 may be an N-type MOSFET.

A first terminal of the decap RTD 940 is connected to a second output node N2 of the inverting F/F circuit 950, and the second electrode of the decap RTD 940 is connected to the gate of the first transistor 930. The decap RTD 940 is connected in series between the first transistor 930 and the second output node N2 to reduce a parasitic capacitance therebetween, thereby reducing the load on the second output node N2.

The inverting F/F circuit 950 includes a second transistor 960, a load RTD 970, and a drive RTD 980. The inverting F/F circuit 950 is similar to the inverting F/F circuit 850 illustrated in FIG. 8 with the exception that the second output node N2, which is the common node of the second transistor 960, the load RTD 970, and the drive RTD 980, is connected through the decap RTD 940 to the first transistor 930 instead of being connected directly to the first transistor 930.

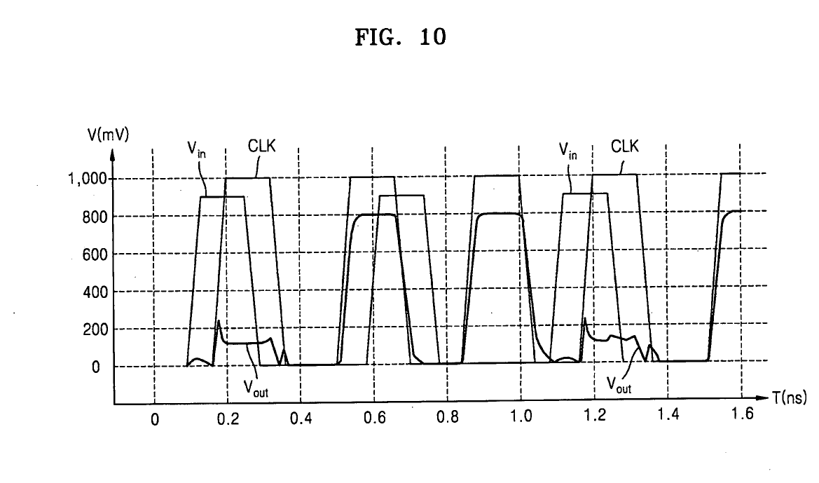

FIG. 10 is a graph illustrating the simulated waveforms of the clock signal CLK, the input data Vᵢₙ, and the output data Vₒᵤₜ according to an embodiment of the present invention.

Referring to FIG. 10, the voltage of the clock signal CLK is about 1 V during the period when the logic level of the clock signal CLK is HIGH. The voltage of the input data Vᵢₙ is about 0.9 V during the period when the logic level of the input data Vᵢₙ is HIGH.

In a case where the logic level of the input data Vᵢₙ is HIGH when the logic level of the clock signal CLK transits from LOW to HIGH, even though the logic level of the input data Vᵢₙ transits from HIGH to LOW, the logic level of the output data Vₒᵤₜ is continuously maintained LOW during the period when the logic level of the clock signal CLK is maintained HIGH.

In another case where the logic level of the input data Vᵢₙ is LOW when the logic level of the clock signal CLK transits from LOW to HIGH, even though the logic level of the input data Vᵢₙ transits from LOW to HIGH, the logic level of the output data Vₒᵤₜ is continuously maintained HIGH during the period when the logic level of the clock signal CLK is maintained HIGH.

That is, the logic level of the output data Vₒᵤₜ is determined depending on the logic level of the input data Vᵢₙ at the time when the logic level of the clock signal CLK transits from LOW to HIGH. Therefore, the MOBILE circuit can provide the Vₒᵤₜ that is stable even though the logic level of the input data Vᵢₙ changes.

As described above, the present invention makes it possible to maintain the logic level HIGH of the output data in the inverting F/F circuit type MOBILE circuit constructed using silicon semiconductor based RTDs with a small PVCR, even when the logic level of the input data changes from LOW to HIGH. Therefore, a malfunction in the inverting F/F circuit type MOBILE circuit can be prevented.

Also, the circuit complexity of the MOBILE circuit can be reduced because the output data fed back from the MOBILE circuit can be provided using only one transistor and one RTD. In addition, the power consumption of the MOBILE circuit can be minimized because the MOBILE circuit operates only when the logic level of the output data is HIGH.

While the present invention has been particularly shown and described with reference to exemplary embodiments thereof, it will be understood by those of ordinary skill in the art that various changes in form and details may be made therein without departing from the spirit and scope of the present invention as defined by the following claims.

What is claimed is:

1. A MOBILE (monostable-bistable transition logic element) circuit constructed using RTDs (resonant tunneling diodes), comprising:
an input data conversion circuit receiving input data and converting a logic level of input data according to a logic level of output data of the MOBILE circuit; and
an inverting F/F (flip-flop) circuit inverting a logic level of data output from the input data conversion circuit and outputting the output data.

2. The MOBILE circuit of claim 1, wherein the input data conversion circuit operates when the logic level of the output data is HIGH.

3. The MOBILE circuit of claim 2, wherein the input data conversion circuit operates when the logic level of the input data changes from LOW to HIGH.

4. The MOBILE circuit of claim 3, wherein the input data conversion circuit converts the logic level of the input data from HIGH to LOW and outputs the resulting data.

5. The MOBILE circuit of claim 4, wherein the input data conversion circuit operates when a logic level of a clock signal input into the inverting F/F circuit is HIGH.

6. The MOBILE circuit of claim 1, wherein the input data conversion circuit comprises:
a first transistor receiving output data of the inverting F/F circuit; and
a first RTD connected to the first transistor and receiving the input data.

7. The MOBILE circuit of claim 6, wherein the first transistor has a first terminal connected to an output node of the inverting F/F circuit, a second terminal connected to ground, and a third terminal connected to an output node of the input data conversion circuit.

8. The MOBILE circuit of claim 7, wherein the first RTD has a first terminal connected to an input node of the input data conversion circuit, and a second terminal connected to the output node of the input data conversion circuit.

9. The MOBILE circuit of claim 8, wherein the inverting F/F circuit comprises:
a second transistor receiving the data output from the input data conversion circuit as a control signal;
a second RTD connected in parallel to the second transistor; and
a third RTD connected in series with the second RTD.

10. The MOBILE circuit of claim 9, wherein the second transistor has a first terminal connected to the output node of the input data conversion circuit, a second terminal connected to the output node of the inverting F/F circuit, and a third terminal connected to ground;
the second RTD has a first terminal connected to the output node of the inverting F/F circuit, and a second terminal connected to ground; and
the third RTD has a first terminal connected to a clock signal input terminal, and a second terminal connected to the output node of the inverting F/F circuit.

11. The MOBILE circuit of claim 1, wherein the RTD is a silicon semiconductor based RTD.

12. The MOBILE circuit of claim 1, wherein the inverting F/F circuit is an inverted return-to-zero D flip-flop.

13. A MOBILE (monostable-bistable transition logic element) circuit constructed using RTDs (resonant tunneling diodes), comprising:
an input data conversion circuit receiving input data and outputting data with a logic level LOW independently of a logic level of the input data when a logic level of output data of the MOBILE circuit is HIGH; and
an inverting F/F (flip-flop) circuit inverting a logic level of data output from the input data conversion circuit and outputting the output data.

14. The MOBILE circuit of claim 13, wherein the input data conversion circuit operates during a period when a logic level of a clock signal input into the inverting F/F circuit is HIGH.

15. The MOBILE circuit of claim 13, wherein the input data conversion circuit comprises:
a first RTD receiving output data of the inverting F/F circuit;
a first transistor receiving output data of the first RTD; and
a second RTD connected to the first transistor and receiving the input data.

16. The MOBILE circuit of claim 15, wherein the first RTD has a first terminal connected to an output node of the inverting F/F circuit, and a second terminal connected to a first terminal of the first transistor.

17. The MOBILE circuit of claim 16, wherein the first transistor has the first terminal connected to the second terminal of the first RTD, a second terminal connected to ground, and a third terminal connected to an output node of the input data conversion circuit.

18. The MOBILE circuit of claim 17, wherein the second RTD has a first terminal connected to an input node of the input data conversion circuit, and a second terminal connected to the output node of the input data conversion circuit.

19. The MOBILE circuit of claim 13, wherein the RTD is a silicon semiconductor based RTD.

20. The MOBILE circuit of claim 13, wherein the inverting F/F circuit is an inverted return-to-zero D flip-flop.
